(19) United States
(12) Patent Application Publication
(10) Pub. No.: US 2014/0001435 A1
(43) Pub. Date: Jan. 2, 2014

(54) ELECTROLUMINESCENT LIGHT SOURCE WITH HIGH LIGHT EMISSION INTENSITY

(71) Applicant: UNIVERSITY OF SOUTH FLORIDA, Tampa, FL (US)

(72) Inventor: Sarath Witanachchi, TAMPA, FL (US)

(21) Appl. No.: 13/932,401

(22) Filed: Jul. 1, 2013

Related U.S. Application Data
(60) Provisional application No. 61/666,461, filed on Jun. 29, 2012.

(51) Int. Cl. H01L 33/28

(52) U.S. Cl. CPC H01L 33/28
USPC 257/13; 438/47

(57) ABSTRACT

Electroluminescent devices, methods of forming the same, and methods of generating light using the same are provided. An electroluminescent device can include an active layer and at least one p-n junction in physical contact with the active layer. Each p-n junction can include a p-type semiconductor layer and an n-type semiconductor layer.

### CROSS-REFERENCE TO RELATED APPLICATION

This application claims the benefit of U.S. Provisional Application Ser. No. 61/666,461, filed Jun. 29, 2012, which is hereby incorporated by reference in its entirety.

### BACKGROUND OF THE INVENTION

Electroluminescent light sources emit light when a voltage is applied. Currently, electroluminescence-based light sources are limited to back light units in television and lighting for signage due to low achievable light emission intensities. A typical electroluminescent device consists of an active layer that is sandwiched directly between two insulating layers, and the active layer consists of a phosphor material. When a high enough voltage is applied across the active layer, electrons accelerated by the electric field collide with the phosphor material to emit light from the active layer. Emission intensity is limited by the electron density, which is very low.

### BRIEF SUMMARY OF THE INVENTION

Embodiments of the subject invention relate to electroluminescent devices, methods of manufacturing the same, and methods of using the same. An electroluminescent device can include an active layer directly in contact with a semiconductor p-n junction (e.g., with a semiconductor layer of a p-n junction).

In an embodiment, an electroluminescent device can include an active layer and at least one p-n junction in physical contact with the active layer, wherein the at least one p-n junction includes a first semiconductor layer and a second semiconductor layer. Either the first semiconductor layer or the second semiconductor layer is a p-type semiconductor layer, and the other is an n-type semiconductor layer.

In another embodiment, a method of forming an electroluminescent device can include: forming a second semiconductor layer directly on and in physical contact with a first semiconductor layer; forming an active layer directly on and in physical contact with the second semiconductor layer; forming a third semiconductor layer directly on and in physical contact with the active layer; and forming a fourth semiconductor layer directly on and in physical contact with the third semiconductor layer. Either the first semiconductor layer or the second semiconductor layer is a p-type semiconductor layer, and the other is an n-type semiconductor layer. Also, either the third semiconductor layer or the fourth semiconductor layer is a p-type semiconductor layer, and the other is an n-type semiconductor layer.

In yet another embodiment, a method of generating light can include providing an electroluminescent device. The device can include an active layer and at least one p-n junction in physical contact with the active layer, wherein the at least one p-n junction includes a first semiconductor layer and a second semiconductor layer. Either the first semiconductor layer or the second semiconductor layer is a p-type semiconductor layer, and the other is an n-type semiconductor layer.

### BRIEF DESCRIPTION OF THE DRAWINGS

FIG. 1A shows a schematic of an electroluminescent device according to an embodiment of the subject invention.

FIG. 1B shows a band diagram for a material that can be used in an electroluminescent device according to an embodiment of the subject invention.

FIG. 1C shows a diagram showing acceleration of electrons in an external electric field.

FIG. 2 shows a schematic of an electroluminescent device according to an embodiment of the subject invention.

FIG. 3 shows a picture of a microwave plasma system used in the growth of layers according to an embodiment of the subject invention.

FIG. 4 shows a microwave plasma reactor that can be used to fabricate nanophosphor/ZnS composite coatings according to an embodiment of the subject invention.

FIG. 5 shows aerosol transport through different stages of the plasma reactor of FIG. 4.

FIG. 6A shows an emission spectrum from chlorophyll.

FIG. 6B shows an emission spectrum from devices with separate phosphor active layers of La₂O₃:Bi and CaS:Eu, according to an embodiment of the subject invention.

FIG. 7 shows TEM images of La₂O₃:Bi nanophosphors formed by a microwave plasma process, according to an embodiment of the subject invention, for: (a) a 0.1M solution, showing 75-100 nm particles; (b) lattice planes at high resolution indicating single crystal nature; (c) a 0.01M solution, particle sizes of 5-6 nm; and (d) lattice planes at high resolution.

FIG. 8 shows XRD patterns of as-deposited La₂O₃:Bi³⁺ nanophosphor coatings at two different power levels indicating crystallinity, according to an embodiment of the subject invention.

FIG. 9A shows a view of a device fabricated with nanoparticle coatings according to an embodiment of the subject invention.

FIG. 9B shows a view of a blue-emitting device with a La₂O₃:Bi phosphor according to an embodiment of the subject invention.

FIG. 9C shows a view of a red-emitting device with a CaS:Eu phosphor according to an embodiment of the subject invention.

FIG. 10A shows a schematic illustrating guiding light out from a multi-layer device according to an embodiment of the subject invention having a substrate with a flat aluminum back and glass in the front.

FIG. 10B shows a schematic illustrating guiding light out from a multi-layer device according to an embodiment of the subject invention having a substrate with a curved aluminum back and a modulated front polymer.

FIG. 11 shows a schematic of band alignment of an electroluminescent device according to an embodiment of the subject invention that is subjected to an external voltage. The inset shows photon emission from impurity ions.

### DETAILED DISCLOSURE OF THE INVENTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present. When the term “directly on” is used herein, when referring to layers, regions, patterns, or structures, it is understood that the layer, region, pattern or structure is directly on another layer or structure, such that no intervening layers, regions, patterns, or structures are present. When the term “direct contact” is used herein, when referring to layers, regions, patterns, or structures in contact with other layers, regions, patterns, or structures, it is understood that the layer, region, pattern or structure is in direct, physical contact with the other layer, region, pattern, or structure, such that no intervening layers, regions, patterns, or structures are present.

When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

Embodiments of the subject invention relate to electroluminescent devices, methods of manufacturing the same, and methods of using the same. An electroluminescent device can include an active layer directly in contact with a semiconductor layer of a p-n junction.

In a typical electroluminescent device, an active layer is sandwiched between two insulating layers. When a high enough voltage is applied across the active layer, electrons at the interface of the active layer and the insulator are accelerated to high energy and collide with phosphor in the active layer to emit light from the active layer. However, emission intensity is limited by the electron density, which is very low in a typical electroluminescent device. Embodiments of the subject invention provide a completely new device architecture that sandwiches the active layer between two semiconductor layers and/or between two semiconductor p-n junctions.

In an embodiment, an electroluminescent device can include an active layer directly in contact with at least one semiconductor layer. Each semiconductor layer in direct contact with the active layer can be part of a p-n junction. For example, the active layer can be between two semiconductor layers, such that the active layer is in contact with both semiconductor layers. In certain embodiments, the active layer can be sandwiched between two semiconductor p-n junctions, such that the top surface of the active layer is in contact with a semiconductor layer and the bottom surface of the active layer is in contact with a semiconductor layer. Each semiconductor layer in direct contact with the active layer can be part of a p-n junction, leading to an enhancement in electron density, thereby generating much higher light intensities than typical electroluminescent devices. This advantageous arrangement also provides an avenue for current injection that can further increase emission intensity.

In many embodiments, the active layer of the electroluminescent device can be a phosphor layer. In a further embodiment, the active layer can include a coating of a phosphor material and/or a coating of phosphor particles embedded in a host material. The host material in which the phosphor particles can be embedded can be crystalline or amorphous. In addition, the host material in which the phosphor particles can be embedded can be inorganic or organic. The phosphor layer, phosphor coating, or phosphor particles can include, for example, zinc sulfide (ZnS), manganese, calcium sulfide (CaS), ZnS nanocrystals, and/or CaS nanocrystals, though embodiments are not limited thereto. In an embodiment of the subject invention, an active layer of an electroluminescent device can include Mn-doped ZnS (ZnS:Mn). In another embodiment, the active layer can include ZnS/CaS nanocrystals. In a further embodiment, the active layer can include ZnS with ZnS/CaS nanocrystal inclusions

The availability of large numbers of phosphors that radiate in a variety of wavelengths and bandwidths, from deep-blue to far-red, enables the development of light sources in many specific wavelength regions. There are two main methods of exciting phosphors; one is optical excitation by a UV source (e.g., UV-LED) followed by emission in higher wavelengths. This method suffers from Stokes down-conversion, where the energy of the emitted photon is much smaller than the energy of the absorbed photon. Another method of exciting phosphors is impact excitation by high energy electrons, and theoretical efficiency for this process is very high. The main loss mechanism is the non-radiative electron-hole recombination. These losses can be compensated by increasing the density of electrons available for excitation.

In an embodiment, a phosphor layer can include a host material impurity ions as active ions. The crystal field energy of the host structure can cause splitting of the energy level in the active ions leading to an absorption line in blue and emission lines at longer wavelengths with long lifetimes (phosphorescence). The host material can be, for example, an oxide, a nitride, or a sulfide material, though embodiments are not limited thereto. The impurity ions can be, for example, any of the following elements or any combination of the following elements, though embodiments are not limited thereto: cerium (Ce), europium (Eu), terbium (Tb), manganese (Mn), copper (Cu), silver (Ag), lead (Pb), and bismuth (Bi). The host material can include a small percentage of impurity ions, for example 0.001% to 10% by weight or by volume, preferably 0.1% to 5% by weight, more preferably 0.5% to 2% by weight, and even more preferably 1% or about 1% by weight. In a particular embodiment, the host material can include about 1% by volume of impurity ions. Other examples of phosphor materials that can be used in the subject invention include some well-known phosphor materials: Ce³⁺ and/or Eu²⁺ doped Y₃Al₅O₁₂ (YAG: Ce³⁺, Eu²⁺), Y₂O₃:Eu²⁺, Ba₃MgSi₂O₈:Eu²⁺, Mn²⁺, ZnS:Mn, CaS:Cu, CaS:Pb²⁺, CaS:Eu²⁺.

In an embodiment, the phosphor material can be ZnS:Mn. Electrons that are accelerated in the conduction band of the ZnS semiconductor interact with Mn ions to produce emission in the orange region. However, most of the phosphor hosts that emit radiation in other wavelengths are oxides, nitrides, or sulfides, which are highly insulating. Embedding particles of these phosphors in a wide band gap semiconductor such as ZnS can increase emission intensities. Phosphor materials fabricated by solid state sintering methods are in micrometer scale, and thus light scattering at grain boundaries can be significant. Light scattering can reduces the extraction efficiency of the source. When the phosphor particle size is few tens of nanometers, much smaller than the wavelength of light (400-800 nm), the effect of light scattering can be significantly reduced. The Mie scattering cross-section of particles below 50 nm is very small. In addition, when the phosphor particle size is reduced to the scale of tens of nanometers, the surface area-to-volume ratio of the material is increased, leading to an increase in the luminous efficiency.

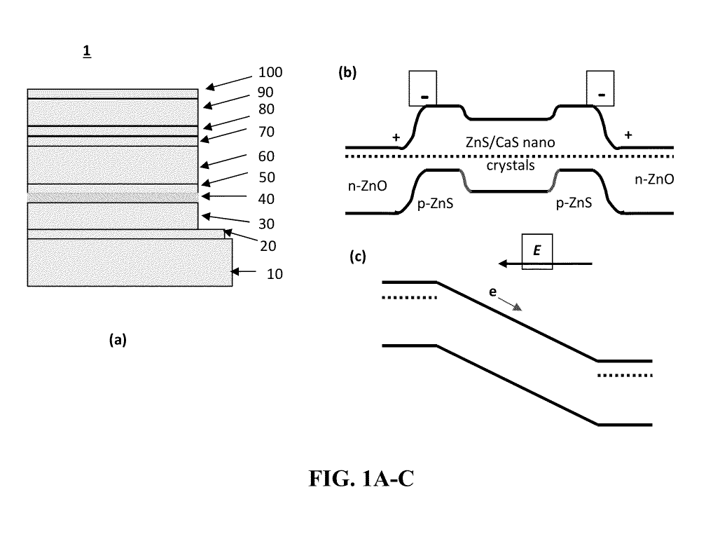

Referring to FIG. 1A, an electroluminescent device according to an embodiment of the subject invention is shown. The electroluminescent device 1 can include a substrate 10, a first conducting layer 20 on the substrate 10, a first insulating layer 30 on the first conducting layer 20, a first semiconductor layer 40 on the first insulating layer 30, a second semiconductor layer 50 on the first semiconductor layer 40, an active layer 60 on the second semiconductor layer 50, a third semiconductor layer 70 on the active layer 60, a fourth semiconductor layer 80 on the third semiconductor layer 70, a second insulating layer 90 on the fourth semiconductor layer 80, and a second conducting layer 100 on the second insulating layer 90. The active layer 60 can be sandwiched between and in direct contact with two semiconductor layers (e.g., the second semiconductor layer 50 and the third semiconductor layer 70). In certain embodiments, one or more of the following layers may not be present: the substrate 10, the first conducting layer 20, the first insulating layer 30, the first semiconductor layer 40, the second semiconductor layer 50, the third semiconductor layer 70, the fourth semiconductor layer 80, the second insulating layer 90, and/or the second conducting layer 100.

In many embodiments, the active layer 60 and at least one of the second semiconductor layer 50 and the third semiconductor layer 70 are present, and the active layer 60 is in direct contact with each of these layers that is present. In an embodiment, the active layer 60 is directly on the second semiconductor layer 50, the second semiconductor layer 50 is directly on the first semiconductor layer 40, and the third 70 and fourth 80 semiconductor layers are not present. The first 40 and second 50 semiconductor layers can be different types (i.e., the first semiconductor layer 40 can be an n-type semiconductor layer and the second semiconductor layer 50 can be a p-type semiconductor layer, or the first semiconductor layer 40 can be a p-type semiconductor layer and the second semiconductor layer 50 can be an n-type semiconductor layer). In an alternative embodiment, the third semiconductor layer 70 is directly on the active layer 60, the fourth semiconductor layer 80 is directly on the third semiconductor layer 70, and the first 40 and second 50 semiconductor layers are not present. The third 70 and fourth 80 semiconductor layers can be different types (i.e., the third semiconductor layer 70 can be a p-type semiconductor layer and the fourth semiconductor layer 80 can be an n-type semiconductor layer, or the third semiconductor layer 70 can be an n-type semiconductor layer and the fourth semiconductor layer 80 can be a p-type semiconductor layer).

Each semiconductor layer 40, 50, 70, 80 (if present) can be either an n-type semiconductor layer or a p-type semiconductor layer. In an embodiment, the first semiconductor layer 40 and the fourth semiconductor layer 80 can be the same type (p-type or n-type), and the second semiconductor layer 50 and the third semiconductor layer 70 can be the same type (p-type or n-type). For example, the first semiconductor layer 40 can be an n-type semiconductor layer, the second semiconductor layer 50 can be a p-type semiconductor layer, the third semiconductor layer 70 can be a p-type semiconductor layer, and the fourth semiconductor layer 80 can be an n-type semiconductor layer. As another example, the first semiconductor layer 40 can be a p-type semiconductor layer, the second semiconductor layer 50 can be an n-type semiconductor layer, the third semiconductor layer 70 can be an n-type semiconductor layer, and the fourth semiconductor layer 80 can be a p-type semiconductor layer.

The active layer 60 can then be sandwiched between two p-n junctions, and the active layer 60 can be in direct contact with two semiconductor layers (e.g., 50 and 70), one semiconductor layer from one of the p-n junctions and one semiconductor layer from the other p-n junction. In addition, each semiconductor layer in direct contact with the active layer 60 can be of the same type (n-type or p-type). For example, the active layer 60 can be directly on a p-type semiconductor layer (e.g., the second semiconductor layer 50) and directly under and in direct contact with a p-type semiconductor layer (e.g., the third semiconductor layer 70). As another example, the active layer 60 can be in directly on an n-type semiconductor layer (e.g., the second semiconductor layer 50) and directly under and in direct contact with an n-type semiconductor layer (e.g., the third semiconductor layer 70).

In another embodiment, the first semiconductor layer 40 and the third semiconductor layer 70 can be the same type (p-type or n-type), and the second semiconductor layer 50 and the fourth semiconductor layer 80 can be the same type (p-type or n-type). The semiconductor layers in direct contact with the active layer 60 can be of different types (n-type or p-type). For example, the active layer 60 can be in directly on a p-type semiconductor layer (e.g., the second semiconductor layer 50) and directly under and in direct contact with an n-type semiconductor layer (e.g., the third semiconductor layer 70). As another example, the active layer 60 can be in directly on an n-type semiconductor layer (e.g., the second semiconductor layer 50) and directly under and in direct contact with a p-type semiconductor layer (e.g., the third semiconductor layer 70).

In a further embodiment, the second 50 and fourth 80 semiconductor layers are not present, and the first 40 and third 70 semiconductor layers are different types (n-type or p-type). For example, the first semiconductor layer 40 can be an n-type semiconductor layer and the third semiconductor layer 70 can be a p-type semiconductor layer, or the first semiconductor layer 40 can be a p-type semiconductor layer and the third semiconductor layer 70 can be an n-type semiconductor layer. The active layer 60 can be in direct contact with both the first semiconductor layer 40 and the third semiconductor layer 70.

Each semiconductor layer (40, 50, 70, and 80) can be any semiconductor layer known in the art, including an inorganic layer or an organic layer. For example, one or more semiconductor layers (40, 50, 70, and 80) can be ZnS, ZnO, an n-type polymer, a p-type polymer, or any combination thereof, though embodiments are not limited thereto.

The first conducting layer 20 (if present) can be either transparent or opaque, and the second conducting layer 100 (if present) can be either transparent or opaque. For example, the first 20 and second conducting layers 100 can either or both be a transparent electrode, such as a layer including indium tin oxide (ITO), carbon nanotubes (CNTs), indium zinc oxide (IZO), and/or a silver nanowire, though embodiments are not limited thereto.

The first insulating layer 30 (if present) and the second insulating layer 90 (if present) can each include any suitable insulating material known in the art, for example, barium titanium oxide (BaTiO₃), a polymer with nanoparticle inclusions (e.g., BaTiO₃ nanoparticle inclusions), silicon dioxide, or any combination thereof, though embodiments are not limited thereto. In an embodiment, the first insulating layer 30 and the second insulating layer 90 can include different materials. In an alternative embodiment, the first insulating layer 30 and the second insulating layer 90 can include the same material or materials.

In an embodiment, the substrate 10 (if present) can include a curved aluminum side and a modulated polymer side (e.g., a curved aluminum back and a modulated polymer front). In further embodiments, the substrate 10 (if present) can be any suitable substrate known in the art, such as a silicon substrate, a metal substrate, a polymer substrate, a glass substrate, or any combination thereof, though embodiments are not limited thereto.

In an embodiment, the electroluminescent device can include a first semiconductor layer 40, a second semiconductor layer 50, an active layer 60, a third semiconductor layer 70, and a fourth semiconductor layer 80. The active layer can be in direct contact with both the second 50 and third 70 semiconductor layers. The first 40 and fourth 80 semiconductor layers can each be n-type semiconductor layers, such as n-type zinc oxide (n-ZnO), and the second 50 and third 70 semiconductor layers can each be p-type semiconductor layers, such as p-type zinc sulfide (p-ZnS). The active layer 60 can include ZnS/CaS nanocrystals. FIG. 1B shows a band diagram for these materials. Referring to FIG. 1B, the valance and conduction bands of each layer is aligned during equilibrium. The depletion layer formed at the ZnO—ZnS interface can cause an accumulation of electrons in ZnS. Referring to FIG. 1C, when a voltage is applied across the active layer 60 (e.g., between the two n-ZnO layers), these electrons are accelerated and are available for impact excitation of the doped impurities. This leads to increased light emission.

The high density of electrons increases the fraction of the available electrons that take part in excitation (η_{exc}) and the fraction of radiating atoms (ηₗᵤₘ) due to high probability of collision. Since energy expenditure on electrons tapped at interfacial sites are no longer needed, most of the electrons will have high energies and therefore the fraction of the hot electrons that have sufficient energy to excite the dopants (ηₕₒₜ) is increased.

The overall efficiency of an electroluminescent device depends on four main contributions: (a) the fraction of the excited dopants that radiatively de-excite (ηₗᵤₘ), which strongly depends on the density of dopants and the density of electrons available for excitation; (b) the fraction of the generated radiation that is extracted due to scattering losses and total-internal-reflection (ηₒᵤₜ); (c) the fraction of the available electrons that take part in excitation (η_{exc}); and (d) the fraction of the hot electrons that have sufficient energy to excite the dopants (ηₕₒₜ), which depends on the binding energy of the localized electrons in interfacial traps and the applied voltage. Therefore the overall efficiency (ηₜₒₜₐₗ), can be given by Equation 1.

ηₜₒₜₐₗ=ηₗᵤₘ+ηₒᵤₜ+η_{exc}+ηₕₒₜ Equation (1).

Electroluminescent devices according to embodiments of the subject invention affect all four contributions and thus enhance the device performance significantly.

In many embodiments, the active layer 60 can be a ZnS film embedded with nanocrystals. The nanocrystals can be, for example, CaS:Pb²⁺, La₂O₃:Bi, CaS:Eu²⁺, or any combination thereof. CaS:Pb²⁺, La₂O₃:Bi can emit in blue, and CaS:Eu²⁺ can emit in red.

In an embodiment, the active layer 60 can be adjacent to an n-type ZnO layer (either the second semiconductor layer 50 or the third semiconductor layer 70), which can be made n-type by oxygen vacancies, and a p-type ZnS layer can be present, which can be made slightly p-type by nitrogen doping during growth. In an alternative embodiment, the ZnO and ZnS layers can be reversed. FIG. 1B shows the alignment of the valance and conduction bands of the active layer, and the semiconductor layers. The depletion layer formed at the ZnO—ZnS interface can cause an accumulation of electrons in ZnS. When a voltage is applied between the two electrodes these electrons can be accelerated and become available for impact excitation of the doped impurities, as shown in FIG. 1C. In addition, an AC current source connected between the top and bottom n-ZnO layers with provisions to control current out can be used to further increase current injection. The high density of electrons can increase the fraction of available electrons that take part in excitation (η_{exc}) and the fraction of radiating atoms (ηₗᵤₘ) due to high probability of collision. Since energy expenditure on electrons tapped at interfacial sites is no longer needed, most of the electrons will have high energies and therefore the fraction of the hot electrons that have sufficient energy to excite the dopants (ηₕₒₜ) is increased. The expected enhancement in the overall luminous efficiency leads to an efficient electroluminescent device. FIG. 11 shows a schematic of band alignment of an electroluminescent device according to an embodiment of the subject invention that is subjected to an external voltage. The inset shows photon emission from impurity ions.

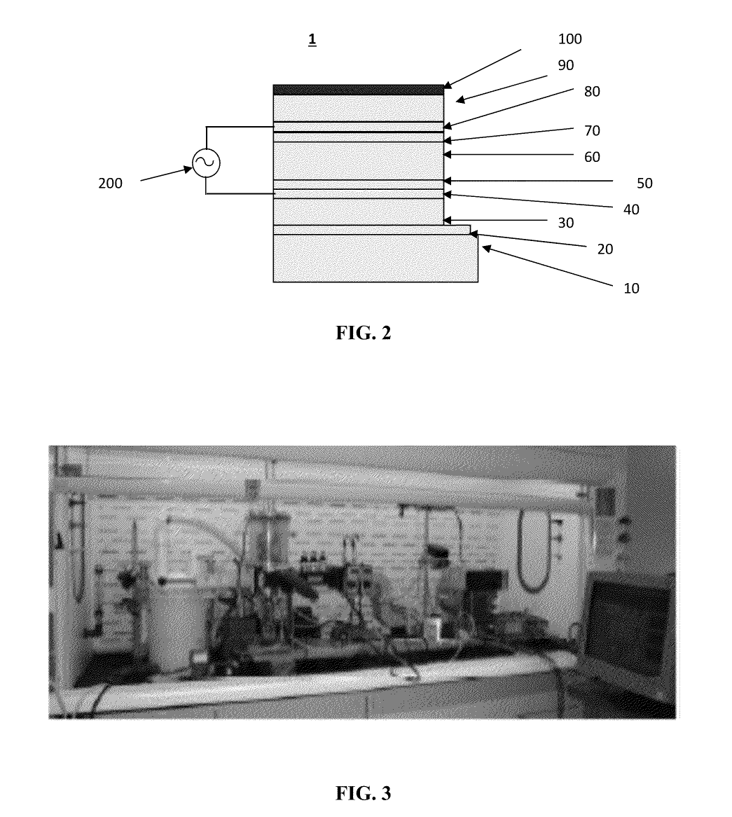

Referring to FIG. 2, in an embodiment, an electroluminescent device can include a current or voltage source 200. The source 200 can be connected between two of the semiconductor layers, one on either side of the active layer 60. For example, as shown in FIG. 2, the source 200 can be connected between the first semiconductor layer 40 and the fourth semiconductor layer 80. In further embodiments, the source 200 can be connected between the first 40 and third 70 semiconductor layers, the second 50 and third 70 semiconductor layers, or the second 50 and fourth 80 semiconductor layers. The source 200 can be any suitable current or voltage source known in the art, and the source can be connected to the semiconductor layers using any suitable connection means known in the art.

The source 200 provides further increase in electron density. When the electrodes (e.g., the two outer electrodes, such as the first 40 and fourth 80 semiconductor layers) are biased with a high voltage, a potential difference exists between these two layers (e.g., these two n-type layers or these two p-type layers). Electrons are injected into the device from the source 200 due to this voltage difference. The amount of current is controlled by an external circuit (not shown), and this allows control of the device power consumption according to the light output required. Any suitable external circuit known in the art can be used.

Advantageously, electroluminescent devices according to embodiments of the subject invention can generate power outputs in a range of 1300 to 1500 μW/cm² (13 to 15 W/m²).

Referring again to FIG. 1A, in an embodiment, a method of forming an electroluminescent device 1 includes forming a first conducting layer 20 on a substrate, forming a first insulating layer 30 on the first conducting layer 20, forming a first semiconductor layer 40 on the first insulating layer 30, forming a second semiconductor layer 50 on the first semiconductor layer 40, forming an active layer 60 on the second semiconductor layer 50, forming a third semiconductor layer 70 on the active layer 60, forming a fourth semiconductor layer 80 on the third semiconductor layer 70, forming a second insulating layer 90 on the fourth semiconductor layer 80, and forming a second conducting layer 100 on the second insulating layer 90. The active layer 60 can be sandwiched between and in direct contact with two semiconductor layers (e.g., the second semiconductor layer 50 and the third semiconductor layer 70). In certain embodiments, one or more of the following layers may not be formed: the substrate 10, the first conducting layer 20, the first insulating layer 30, the first semiconductor layer 40, the second semiconductor layer 50, the third semiconductor layer 70, the fourth semiconductor layer 80, the second insulating layer 90, and/or the second conducting layer 100.

In many embodiments, the active layer 60 and at least one of the second semiconductor layer 50 and the third semiconductor layer 70 are present, and the active layer 60 is in direct contact with each of these layers that is present. In an embodiment, the second semiconductor layer 50 is formed directly on the first semiconductor layer 40, the active layer 60 is formed directly on the second semiconductor layer 50, and the third 70 and fourth 80 semiconductor layers are not formed. The first 40 and second 50 semiconductor layers can be different types (i.e., the first semiconductor layer 40 can be an n-type semiconductor layer and the second semiconductor layer 50 can be a p-type semiconductor layer, or the first semiconductor layer 40 can be a p-type semiconductor layer and the second semiconductor layer 50 can be an n-type semiconductor layer). In an alternative embodiment, the third semiconductor layer 70 is formed directly on the active layer 60, the fourth semiconductor layer 80 is formed directly on the third semiconductor layer 70, and the first 40 and second 50 semiconductor layers are not formed. The third 70 and fourth 80 semiconductor layers can be different types (i.e., the third semiconductor layer 70 can be a p-type semiconductor layer and the fourth semiconductor layer 80 can be an n-type semiconductor layer, or the third semiconductor layer 70 can be an n-type semiconductor layer and the fourth semiconductor layer 80 can be a p-type semiconductor layer).

In an embodiment, the active layer 60 can be sandwiched between two p-n junctions, and the active layer 60 can be in direct contact with two semiconductor layers (e.g., 50 and 70), one semiconductor layer from one of the p-n junctions and one semiconductor layer from the other p-n junction. In addition, each semiconductor layer in direct contact with the active layer 60 can be of the same type (n-type or p-type). For example, the active layer 60 can be directly on a p-type semiconductor layer (e.g., the second semiconductor layer 50) and directly under and in direct contact with a p-type semiconductor layer (e.g., the third semiconductor layer 70). As another example, the active layer 60 can be in directly on an n-type semiconductor layer (e.g., the second semiconductor layer 50) and directly under and in direct contact with an n-type semiconductor layer (e.g., the third semiconductor layer 70).

In an embodiment, the electroluminescent device can include a first semiconductor layer 40, a second semiconductor layer 50, an active layer 60, a third semiconductor layer 70, and a fourth semiconductor layer 80. The active layer can be in direct contact with both the second 50 and third 70 semiconductor layers. The first 40 and fourth 80 semiconductor layers can each be n-type semiconductor layers, such as n-ZnO, and the second 50 and third 70 semiconductor layers can each be p-type semiconductor layers, such as p-ZnS. The active layer 60 can include ZnS/CaS nanocrystals.

Referring again to FIG. 2, in an embodiment, a method of forming an electroluminescent device can include forming a current or voltage source 200 or connecting a current or voltage source 200 to two semiconductor layers of the device. The source 200 can be connected between two of the semiconductor layers, one on either side of the active layer 60. For example, as shown in FIG. 2, the source 200 can be connected between the first semiconductor layer 40 and the fourth semiconductor layer 80. In further embodiments, the source 200 can be connected between the first 40 and third 70 semiconductor layers, the second 50 and third 70 semiconductor layers, or the second 50 and fourth 80 semiconductor layers. The source 200 can be any suitable current or voltage source known in the art, and the source can be connected to the semiconductor layers using any suitable connection means known in the art.

In an embodiment, a method of generating light can include providing an electroluminescent device as described herein.

### EXEMPLIFIED EMBODIMENTS

The invention includes, but is not limited to, the following embodiments:

### Embodiment 1

An electroluminescent device, including:
an active layer; and
at least one p-n junction in physical contact with the active layer, wherein the at least one p-n junction includes a first semiconductor layer and a second semiconductor layer, wherein one of the first semiconductor layer and the second semiconductor layer is a p-type semiconductor layer and the other is an n-type semiconductor layer.

### Embodiment 2

The electroluminescent device according to embodiment 1, wherein the device includes:
a first p-n junction directly under and in physical contact with the active layer; and
a second p-n junction directly on and in physical contact with the active layer,

wherein the first p-n junction includes the first semiconductor layer and the second semiconductor layer,

wherein the second p-n junction includes a third semiconductor layer and a fourth semiconductor layer, and

wherein one of the third semiconductor layer and the fourth semiconductor layer is a p-type semiconductor layer and the other is an n-type semiconductor layer.

### Embodiment 3

The electroluminescent device according to embodiment 2, further including:
a substrate;
a first conducting layer on the substrate;
a first insulating layer on the first conducting layer;
a second insulating layer on the second p-n junction; and
a second conducting layer on the second insulating layer,

wherein the first p-n junction is on the first insulating layer.

### Embodiment 4

The electroluminescent device according to any of embodiments 2-3, wherein the active layer includes zinc sulfide/calcium sulfide nanocrystals (ZnS/CaS nanocrystals),

wherein the first semiconductor layer includes n-type zinc oxide (n-ZnO),

wherein the second semiconductor layer is directly under and in physical contact with the active layer and includes p-type zinc sulfide (p-ZnS),

wherein the third semiconductor layer is directly on and in physical contact with the active layer and includes p-ZnS, and

wherein the fourth semiconductor layer includes n-ZnO.

### Embodiment 5

The electroluminescent device according to any of embodiments 2-4, further including a current source connected between the first semiconductor layer and the fourth semiconductor layer.

### Embodiment 6

The electroluminescent device according to any of embodiments 2-5, further including at least one layer selected from the following group:

a first insulating layer directly under and in physical contact with the first p-n junction; and

a second insulating layer directly on and in physical contact with the second p-n junction.

### Embodiment 7

The electroluminescent device according to any of embodiments 2-6, further including at least one layer selected from the following group:

a first conducting layer under the first p-n junction; and

a second conducting layer on the second p-n junction.

### Embodiment 8

The electroluminescent device according to embodiment 7, wherein each conducting layer is transparent.

### Embodiment 9

The electroluminescent device according to any of embodiments 1-8, wherein the active layer includes at least one material selected from the following group:
a phosphor layer;
a coating of phosphor material; and
phosphor particles embedded in a host material, wherein the host material is crystalline or amorphous.

### Embodiment 10

The electroluminescent device according to any of embodiments 1-5 and 7-9, further including an insulating layer in physical contact with at least one p-n junction.

### Embodiment 11

A method of forming an electroluminescent device, including:
forming a second semiconductor layer directly on and in physical contact with a first semiconductor layer;
forming an active layer directly on and in physical contact with the second semiconductor layer;
forming a third semiconductor layer directly on and in physical contact with the active layer; and
forming a fourth semiconductor layer directly on and in physical contact with the third semiconductor layer,
wherein one of the first semiconductor layer and the second semiconductor layer is a p-type semiconductor layer and the other is an n-type semiconductor layer, and
wherein one of the third semiconductor layer and the fourth semiconductor layer is a p-type semiconductor layer and the other is an n-type semiconductor layer.

### Embodiment 12

The method according to embodiment 11, wherein the active layer includes at least one material selected from the following group:
a phosphor layer;
a coating of phosphor material; and
phosphor particles embedded in a host material, wherein the host material is crystalline or amorphous.

### Embodiment 13

The method according to any of embodiments 11-12, further including connecting a current source connected between the first semiconductor layer and the fourth semiconductor layer.

### Embodiment 14

The method according to any of embodiments 11-13, further including:
forming a first conducting layer on a substrate;
forming a first insulating layer on the first conducting layer;
forming the first semiconductor layer on the first insulating layer;
forming a second insulating layer on the fourth semiconductor layer; and
forming a second conducting layer on the second insulating layer.

### Embodiment 15

The method according to any of embodiments 11-14, wherein the active layer includes ZnS/CaS nanocrystals,

wherein the first semiconductor layer includes n-ZnO,

wherein the second semiconductor includes p-ZnS,

wherein the third semiconductor layer includes p-ZnS, and

wherein the fourth semiconductor layer includes n-ZnO.

### Embodiment 16

A method of generating light, including:

providing an electroluminescent device, wherein the device includes:
an active layer; and
at least one p-n junction in physical contact with the active layer, wherein the at least one p-n junction includes: a first semiconductor layer and a second semiconductor layer, wherein one of the first semiconductor layer and the second semiconductor layer is a p-type semiconductor layer and the other is an n-type semiconductor layer.

### Embodiment 17

The method according to embodiment 16, wherein the device includes:
a first p-n junction directly under and in physical contact with the active layer; and
a second p-n junction directly on and in physical contact with the active layer,

wherein the first p-n junction includes the first semiconductor layer and the second semiconductor layer,

wherein the second p-n junction includes a third semiconductor layer and a fourth semiconductor layer,

wherein one of the third semiconductor layer and the fourth semiconductor layer is a p-type semiconductor layer and the other is an n-type semiconductor layer, and

### Embodiment 18

The method according to any of embodiments 16-17, wherein the active layer includes at least one material selected from the following group:
a phosphor layer;
a coating of phosphor material; and

phosphor particles embedded in a host material, wherein the host material is crystalline or amorphous.

### Embodiment 19

The method according to any of embodiments 16-18, further including:
connecting a current source between the first semiconductor layer and the fourth semiconductor layer; and
providing a voltage across the active layer using the current source.

All patents, patent applications, provisional applications, and publications referred to or cited herein are incorporated by reference in their entirety, including all figures and tables, to the extent they are not inconsistent with the explicit teachings of this specification.

Following are examples that illustrate procedures for practicing the invention. These examples should not be construed as limiting. All percentages are by weight and all solvent mixture proportions are by volume unless otherwise noted.

### Example 1

An electroluminescent device was prepared including an active layer sandwiched between two p-n junctions. A first conducting layer was formed on a substrate, a first insulating layer was formed on the first conducting layer, an n-ZnO layer was formed on the first conducting layer, a p-ZnS layer was formed on the n-ZnO layer, an active layer including ZnS/CaS nanocrystals was formed on the p-ZnS layer, another p-ZnS layer was formed on the active layer, another n-ZnO layer was formed on the p-ZnS layer, a second insulating layer was formed on the n-ZnO layer, and a second conducting layer was formed on the second insulating layer. The band diagram for the p-n junctions and the active layer is shown in FIG. 1B.

### Example 2

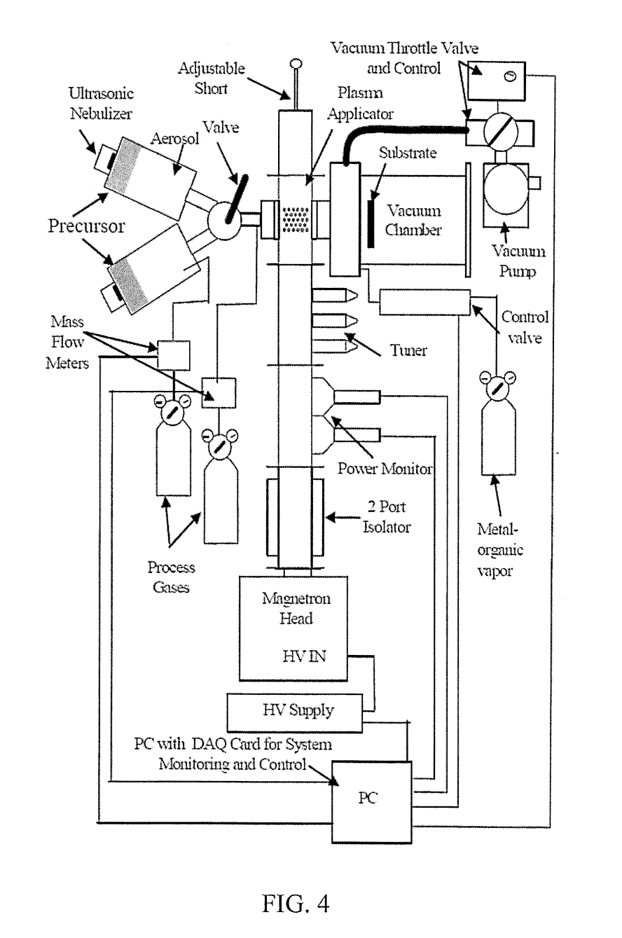

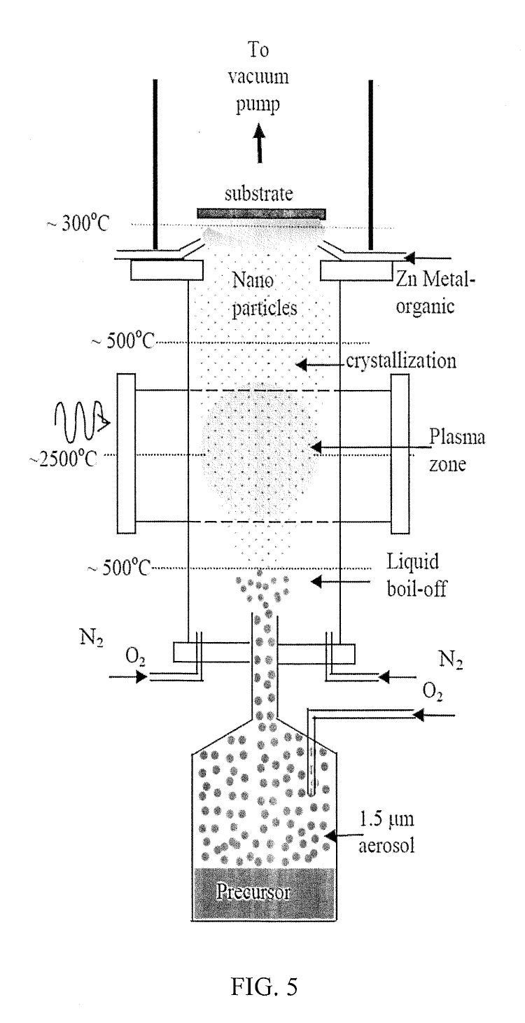

A microwave plasma system for nanoparticle growth was used and consisted of three main regions: (1) nebulizer for 1-1.5 μm aerosol droplets of a precursor; (2) plasma reaction zone where microwave energy generates a high temperature reaction zone for evaporation of solvents and reaction of the chemicals in droplets and plasma gas to form nanophosphors; and (3) substrate placed above the plasma zone for deposition of nanophosphors. The system was modified to accommodate chemical vapor deposition (CVD) of ZnO and ZnS. ZnO coatings were grown by introducing zinc acetylacetonate (Zn(acac)₂) vapor as precursor near the substrate. Vapor was generated by heating granules of Zn(acac)₂ in a container to 160° C. and pushing the vapor with gas that contained a mixture of argon (Ar) and oxygen. Dimethylzinc and H₂S were used for the growth of ZnS films. For safe handling of the chemicals involved, the entire system was place in a fume hood, a picture of which is shown in FIG. 3. Schematics of the microwave plasma system with CVD provisions are shown in FIGS. 4 and 5.

The starting point in the fabrication of this structure, a cross section of which is similar to that depicted in FIG. 1A, is a commercially available ITO-coated glass substrate. The choice of the insulator was barium titanium oxide (BaTiO₃; BTO), which has a refractive index (n) of 2.01. BTO and n-ZnO (n=2.0) films were deposited by sputtering.

ZnO films were also grown by the CVD process within the microwave plasma system on sputtered BTO films. Growth by CVD is much simpler and cost effective than sputtering. ZnS films were deposited by CVD process with dimethylzinc and H₂S gas.

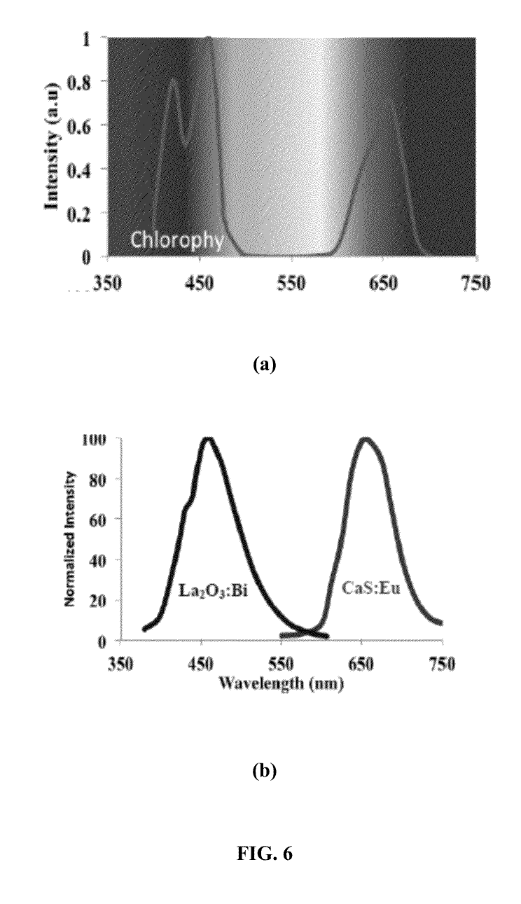

The two phosphor materials to be used to generate blue and red radiation were La₂O₃:Bi (blue) and CaS:Eu²⁺ (red), respectively. La₂O₃:Bi nanoparticles were grown by the microwave plasma process with starting precursors containing aqueous solutions of the nitrates of lanthanum (La) and bismuth (Bi) salts. Depending on the starting concentration, particles of sizes from 5 nm to 100 nm were deposited. Spectrum of light emitted by devices with the two phosphors (separately) and the comparison with a chlorophyll absorption spectrum are shown in FIGS. 6B and 6A, respectively. CaS:Eu nanophosphor coatings were grown in two steps. In the first step, CaS:Eu nanoparticles of sizes of about 50 nm were grown by a solvothermal process. Subsequently, particles were dispersed in ethanol and nebulized in the microwave plasma system to deposit a coating on a substrate. Layers of ZnO films were grown by a CVD process within the microwave plasma system on sputtered BTO films, and ZnS films were deposited by CVD process with dimethylzinc and H₂S gas.

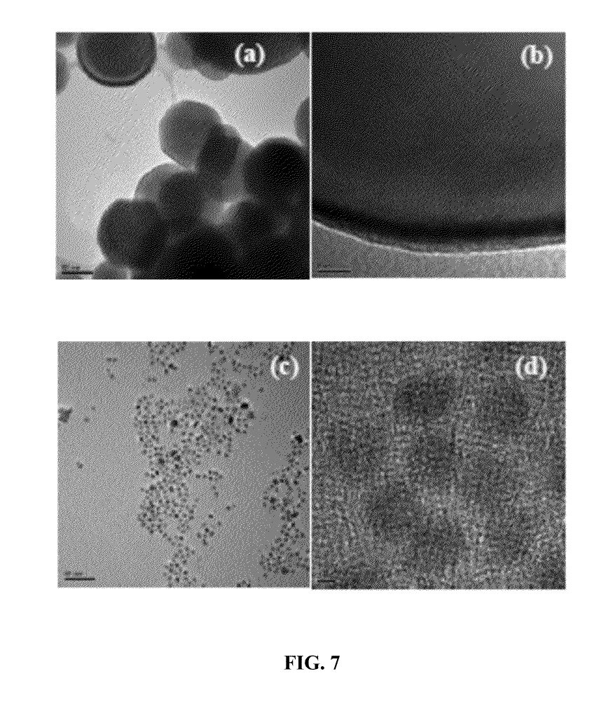

The microwave plasma process allows control of nanophosphor particle sizes by controlling the precursor concentration. La₂O₃:Bi nanophosphors were deposited in single crystal form with sizes from 5 nm to 100 nm by changing the starting concentration. Transmission Electron Microscopy (TEM) images in FIGS. 7A and 7B show the hexagonal crystals in the size range of 75 nm to 100 nm with clear lattice planes with d=3.34 Å that corresponds to (100) orientation. FIGS. 7C and 7D show a uniform size distribution of single crystals in the range of 5 nm to 7 nm.

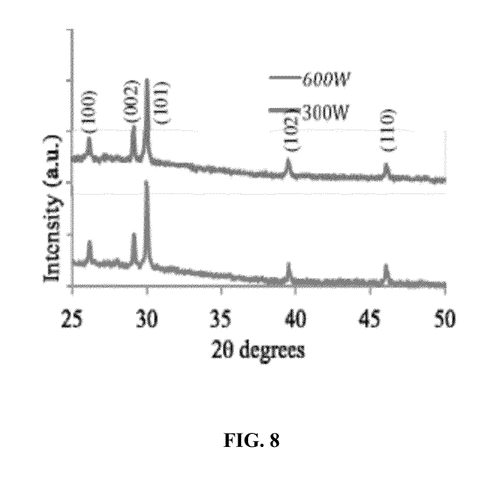

The second BTO layer was sputter deposited at low temperature. Silver ink was used as the back electrode. Each coating was analyzed by X-ray diffraction for crystallinity and absorption spectroscopy for light transmission. FIG. 8 shows X-ray scans of nanoparticle coatings grown under two different microwave powers. In addition to the n-ZnO/p-ZnS p-n junction structure, n-ZnO-p-NiO junctions were also investigated. Since one of the blue phosphors under consideration is La₂O₃:Bi, the possibility of embedding oxide phosphor in a p-type oxide semiconductor rather than ZnS was explored.

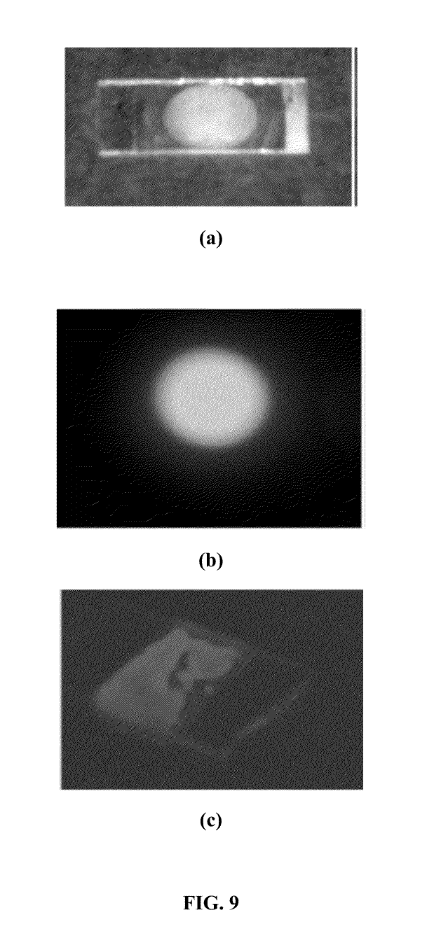

Light output measurements: One of the devices fabricated by the steps outlined above and the observed blue and red emission from these devices are shown in FIGS. 9A-C. Radiant flux emitted was measured by an integrated sphere technique. The blue and red emissions were 720 μW and 800 μW, respectively, compared to 540 μW and 580 μW for a typical existing electroluminescent device. These measurements are for an emission area of 1 cm×1 cm. These values represent an average of 5 similar devices. Even though the absolute values of emission are low, these measurements show an enhancement in emission resulting from the advantageous structure of the subject invention.

Light emitting from each excited doped ion is directed radially in 3D. The light falling on the opaque back contact is reflected to the front. The percentage of light that is extracted from the front surface can be dependent on the refractive indices of the layers. The refractive indices of the materials forming the layers, (e.g., ZnS, CdS, ZnO, BTO, and ITO), are in the range of 2.01 to 2.3. The refractive index of BTO nanoparticle embedded polyimide, which can be spin-coated as the transparent insulating layer, can approach values closer to 1.99. Therefore, the critical angles for total internal reflection are large and most of the light is directed towards the glass substrate. However, the critical angle at the glass-air interface is closer to about 45.6°, which corresponds to an angle of about 28° at the film-glass interface.

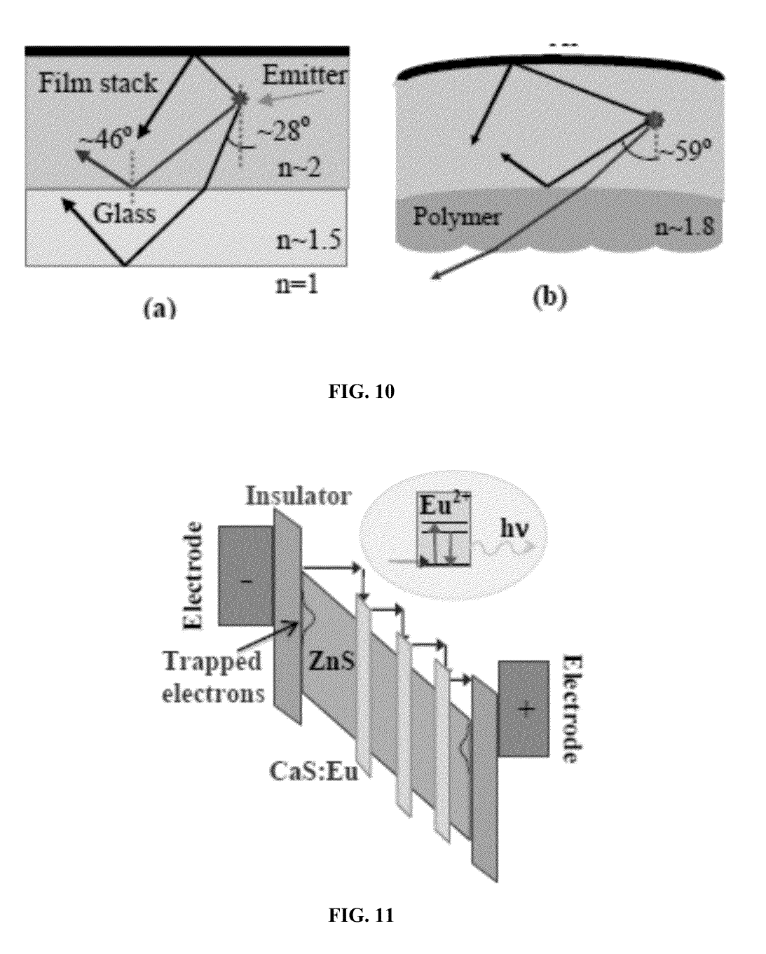

Therefore, referring to FIG. 10A, only about 32% of the light emanating from an excited ion will exit from the front surface in this particular device. One of the ways of increasing this number to over 80% is by using a slightly curved substrate (e.g., a curved aluminum substrate) and a polymer substrate with a modulation as shown in FIG. 10B. This mechanism can be adopted in 10 cm×100 cm electroluminescent strips by introducing a small curvature in the narrow dimension.

The BTO, ZnO, ZnS, and/or phosphor/ZnS composite coatings can be evaluated by one or more of the following methods: Morphological and Structural evaluation, such as atomic force microscopy (AFM), scanning electron microscopy (SEM-EDX), and X-ray diffraction (XRD); Optical characterization, such as emission, absorption, and photoluminescence spectroscopy (PL); and/or Optical emission intensity, such as being measured by an integrated sphere.

It should be understood that the examples and embodiments described herein are for illustrative purposes only and that various modifications or changes in light thereof will be suggested to persons skilled in the art and are to be included within the spirit and purview of this application. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

What is claimed is:

1. An electroluminescent device, comprising:
an active layer; and
at least one p-n junction in physical contact with the active layer, wherein the at least one p-n junction comprises a first semiconductor layer and a second semiconductor layer, wherein one of the first semiconductor layer and the second semiconductor layer is a p-type semiconductor layer and the other is an n-type semiconductor layer.

2. The electroluminescent device according to claim 1, wherein the device comprises:
a first p-n junction directly under and in physical contact with the active layer; and
a second p-n junction directly on and in physical contact with the active layer,
wherein the first p-n junction comprises the first semiconductor layer and the second semiconductor layer,
wherein the second p-n junction comprises a third semiconductor layer and a fourth semiconductor layer, and
wherein one of the third semiconductor layer and the fourth semiconductor layer is a p-type semiconductor layer and the other is an n-type semiconductor layer.

3. The electroluminescent device according to claim 2, wherein the active layer comprises at least one material selected from the following group:
a phosphor layer;
a coating of phosphor material; and
phosphor particles embedded in a host material, wherein the host material is crystalline or amorphous.

4. The electroluminescent device according to claim 2, further comprising a current source connected between the first semiconductor layer and the fourth semiconductor layer.

5. The electroluminescent device according to claim 2, further comprising:
a substrate;
a first conducting layer on the substrate;
a first insulating layer on the first conducting layer;
a second insulating layer on the second p-n junction; and
a second conducting layer on the second insulating layer,
wherein the first p-n junction is on the first insulating layer.

6. The electroluminescent device according to claim 5, wherein the active layer comprises zinc sulfide/calcium sulfide nanocrystals (ZnS/CaS nanocrystals),
wherein the first semiconductor layer comprises n-type zinc oxide (n-ZnO),
wherein the second semiconductor layer is directly under and in physical contact with the active layer and comprises p-type zinc sulfide (p-ZnS),
wherein the third semiconductor layer is directly on and in physical contact with the active layer and comprises p-ZnS, and
wherein the fourth semiconductor layer comprises n-ZnO.

7. The electroluminescent device according to claim 6, further comprising a current source connected between the first semiconductor layer and the fourth semiconductor layer.

8. The electroluminescent device according to claim 2, further comprising at least one layer selected from the following group:
a first insulating layer directly under and in physical contact with the first p-n junction; and
a second insulating layer directly on and in physical contact with the second p-n junction.

9. The electroluminescent device according to claim 2, further comprising at least one layer selected from the following group:
a first conducting layer under the first p-n junction; and
a second conducting layer on the second p-n junction.

10. The electroluminescent device according to claim 9, wherein each conducting layer is transparent.

11. The electroluminescent device according to claim 1, wherein the active layer comprises at least one material selected from the following group:
a phosphor layer;
a coating of phosphor material; and
phosphor particles embedded in a host material, wherein the host material is crystalline or amorphous.

12. The electroluminescent device according to claim 1, further comprising an insulating layer in physical contact with at least one p-n junction.

13. A method of forming an electroluminescent device, comprising:
forming a second semiconductor layer directly on and in physical contact with a first semiconductor layer;
forming an active layer directly on and in physical contact with the second semiconductor layer;
forming a third semiconductor layer directly on and in physical contact with the active layer; and
forming a fourth semiconductor layer directly on and in physical contact with the third semiconductor layer,
wherein one of the first semiconductor layer and the second semiconductor layer is a p-type semiconductor layer and the other is an n-type semiconductor layer, and
wherein one of the third semiconductor layer and the fourth semiconductor layer is a p-type semiconductor layer and the other is an n-type semiconductor layer.

14. The method according to claim 13, wherein the active layer comprises at least one material selected from the following group:
a phosphor layer;
a coating of phosphor material; and
phosphor particles embedded in a host material, wherein the host material is crystalline or amorphous.

15. The method according to claim 13, further comprising connecting a current source between the first semiconductor layer and the fourth semiconductor layer.

16. The method according to claim 13, further comprising:
forming a first conducting layer on a substrate;
forming a first insulating layer on the first conducting layer;
forming the first semiconductor layer on the first insulating layer;
forming a second insulating layer on the fourth semiconductor layer; and
forming a second conducting layer on the second insulating layer.

17. The method according to claim 13, wherein the active layer comprises ZnS/CaS nanocrystals,
wherein the first semiconductor layer comprises n-ZnO,
wherein the second semiconductor comprises p-ZnS,
wherein the third semiconductor layer comprises p-ZnS, and
wherein the fourth semiconductor layer comprises n-ZnO.

18. A method of generating light, comprising:
providing an electroluminescent device, wherein the device comprises:
an active layer; and
at least one p-n junction in physical contact with the active layer, wherein the at least one p-n junction comprises a first semiconductor layer and a second semiconductor layer, wherein one of the first semiconductor layer and the second semiconductor layer is a p-type semiconductor layer and the other is an n-type semiconductor layer.

19. The method according to claim 18, wherein the device comprises:
a first p-n junction directly under and in physical contact with the active layer; and
a second p-n junction directly on and in physical contact with the active layer,
wherein the first p-n junction comprises the first semiconductor layer and the second semiconductor layer,
wherein the second p-n junction comprises a third semiconductor layer and a fourth semiconductor layer,
wherein one of the third semiconductor layer and the fourth semiconductor layer is a p-type semiconductor layer and the other is an n-type semiconductor layer, and
wherein the active layer comprises at least one material selected from the following group:
a phosphor layer;
a coating of phosphor material; and
phosphor particles embedded in a host material, wherein the host material is crystalline or amorphous.

20. The method according to claim 19, further comprising:
connecting a current source between the first semiconductor layer and the fourth semiconductor layer; and
providing a voltage across the active layer using the current source.
